(19) United States
(12) Patent Application Publication
(10) Pub. No.: US 2006/0257795 A1
(43) Pub. Date: Nov. 16, 2006

(54) METHOD FOR FORMING COMPOSITE PATTERN INCLUDING DIFFERENT TYPES OF PATTERNS

(76) Inventor: Benjamin Szu-Min Lin, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,512

(22) Filed: May 16, 2005

(51) Int. Cl. G03F 7/26

(52) U.S. Cl. 430/316; 430/313

(57) ABSTRACT

A method for forming a composite pattern including different types of patterns is described. A substrate having a material layer thereon is provided, and two or more masks each having at least one type of pattern thereon are provided, wherein an imaginary pattern defined by the overlap between the patterns of all of the masks includes the at least one type of pattern of each mask. The following steps (1)-(3) are then performed for multiple cycles, with a different mask being used in each cycle, until all of the masks have been used. In step (1), one mask is used to form one photoresist pattern over the substrate. In step (2), the material layer is etched using the photoresist pattern as a mask. In step (3), the photoresist pattern is removed.

### BACKGROUND OF THE INVENTION

1. Field of the Invention

The present invention relates to patterning processes for fabricating IC devices. More particularly, the present invention relates to a method for forming a composite pattern that includes different types of patterns, especially narrower and wider patterns, with more than one masks and etching steps.

2. Description of the Related Art

In IC manufacturing, a composite pattern including different types of patterns, e.g., narrower and wider patterns, can be formed using more than one masks of different types. For example, U.S. Pat. No. 6,573,010 to Kling et al. teaches a double-exposure method for forming gate line patterns with wider portions on the field oxide, wherein an alternating phase-shift mask (Alt-PSM) is used to define the narrower gate regions and a binary mask is used to define the wider portions.

FIG. 1A illustrates a similar split-gate pattern 100 with wider portions 100a and narrower portions 100b, and FIGS. 1B and 1C illustrate respectively an Alt-PSM 10 and a binary mask 20 that are used together to define 100. The Alt-PSM 10 includes an opaque layer 12 and pairs of π-shift regions 14 and zero-shift regions 16 therein. As indicated by the imaginary pattern 100′ of the pattern 100, the portion of the opaque layer 12 between a pair of π-shift region 14 and zero-shift region 16 defines a narrower portion 100b, and the opaque layer 1 2 also covers the corresponding areas of the wider portions 110a. The binary mask 20 includes a transparent substrate 20 and a mask pattern 24 thereon including the patterns of the wider portions 110b and also covering the corresponding areas of the narrower portions 110a. It is noted that the imaginary pattern defined by the overlap between the patterns of the two masks 10 and 20 is just the target pattern 100.

FIG. 2 illustrates a method for forming such a split-gate pattern in the prior art. Referring to FIG. 2A, after a positive photoresist layer 200 is formed, double-exposure is performed to the photoresist layer 200 using the Alt-PSM 10 and the binary mask 20. The Alt-PSM 10 causes exposed portions 200b and the binary mask 20 causes exposed portions 200a overlapping with 200b. After the development, the unexposed portions 200c of the photoresist layer 200 remain to be the target pattern, as shown in FIG. 2B. A trimming step is then performed to 200c to further reduce the width of the narrower portions 200e to a predetermined value. The wider portions are labeled with 200d.

However, because the trimming effect is isotropic, the line end of each narrower portion 200e having a line end is also shortened, so that the predetermined line length cannot be achieved and the required electrical characteristics cannot be obtained.

### SUMMARY OF THE INVENTION

In view of the foregoing, the present invention provides a method for forming a composite pattern, which includes different types of patterns, with more than one masks and etched steps.

Another object of this invention is to provide a method for forming a pattern having a narrower portion and a wider portion with two masks and two etched steps.

Still another object of this invention is to provide a method for forming a gate line pattern or a split-gate pattern that includes a narrower gate region having a line end, which does not suffer from the line-end shortening problem.

The method for forming a composite pattern including different types of patterns of this invention is described as follows. A substrate having a material layer thereon and multiple masks each having at least one type of pattern thereon are provided. Then, the following steps (1)-(3) are conducted for multiple cycles, with a different mask being used in each cycle, until all of the masks have been used. In step (1), one mask is used to form one photoresist pattern over the substrate. In step (2), the material layer is etched/patterned with the photoresist pattern as a mask. In step (3), the photoresist pattern is removed. In the method, the imaginary pattern defined by the overlap between the patterns of all of the masks includes the at least one type of pattern of each mask.

The method for forming a target pattern having a narrower portion and a wider portion is based on the above method for forming a composite pattern of this invention, wherein two masks including a first mask and a second mask are used, and an etching step is conducted after each mask is used to formed a photoresist pattern. The pattern of the first mask includes the pattern of the narrower portion and also covers the area of the wider portion, and the pattern of the second mask includes the pattern of the wider portion and also covers the area of the narrower portion. In the method, the first mask can be used before or after the second mask, and an additional trimming step may be conducted after the first mask is used to further reduce the width of the narrower portion.

In an embodiment of this invention, the narrower portion of the target pattern has a line end, and the first mask has an opaque layer and two transparent regions in the opaque layer thereon. The portion of the opaque layer between the two transparent regions defines the narrower portion, and the second pattern of the second mask has a boundary passing the corresponding position of the line end on the second mask. Thus, a line end of the narrower portion can be defined by the boundary of the photoresist pattern formed with the second mask. Such a first mask may be an Alt-PSM, for example, where the two transparent regions in the opaque layer are a pair of zero-shift region and π-shift region.

In addition, the target pattern in the above embodiment may be a gate line pattern with narrower gate regions and wider portions on field oxide, while the gate line pattern may be a split-gate pattern.

According to the above embodiment of this invention, since the first mask causes two openings separated by a narrower pattern to form in the first photoresist layer, there is no line end of the first photoresist pattern, while the line end of the target pattern is defined by the non-trimmed second photoresist pattern formed with the second mask. Therefore, the trimming after formation of the first photoresist pattern merely reduces the width of the narrower pattern of the first photoresist pattern, so that the narrower portion of the patterned material layer has a reduced width without line-end shortening.

It is to be understood that both the foregoing general description and the following detailed description are exemplary, and are intended to provide further explanation of the invention as claimed.

### BRIEF DESCRIPTION OF THE DRAWINGS

FIG. 1A illustrates a split-gate pattern with narrower and wider portions, and FIGS. 1B and 1C illustrate respectively an Alt-PSM and a binary mask that are used in combination to define the split-gate pattern in the prior art.

FIG. 2 illustrates a method for forming the split-gate pattern of FIG. 1A in the prior art.

FIG. 3 illustrates a flow of a method for forming a target pattern including wider and narrower portions according to a preferred embodiment of this invention.

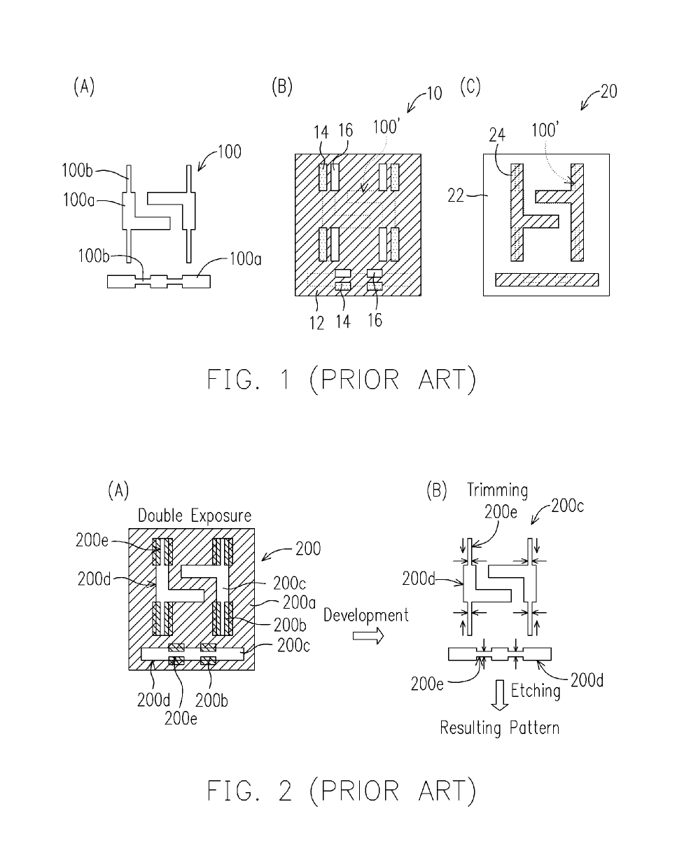

### DESCRIPTION OF THE PREFERRED EMBODIMENTS

This invention will be further explained with formation of a pattern including wider and narrower portions as an example, which is not intended to restrict the scope of this invention. This invention can also be applied to the cases where more than two masks are used to define a more complex composite pattern.

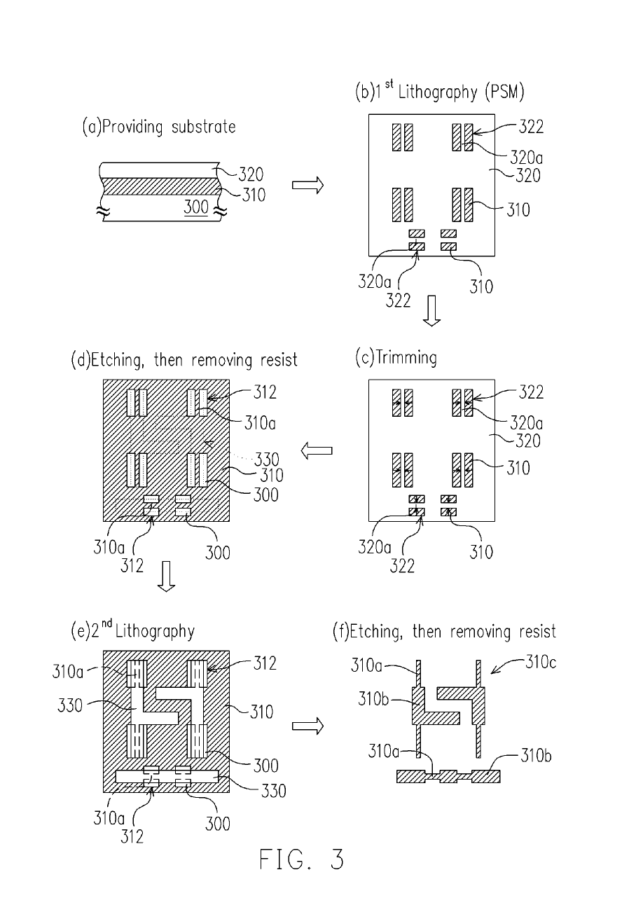

FIG. 3 illustrates a flow of a method for forming a target pattern including wider and narrower portions according to the preferred embodiment of this invention. In step (a), a substrate 300 is provided, and then a material layer 310 to be patterned and a photoresist layer 320 are sequentially formed on the substrate 300, wherein the material layer 310 may be a polysilicon layer that will later be defined into a gate line pattern or a split-gate pattern, for example. When the target pattern 310c as shown in step (f) is a gate line pattern or split-gate pattern, the wider portions 310b may be the portions of the gate line pattern located on the field isolation layer, and the narrower portions 310a may be the gate regions over the active areas. The field isolation layer and the active areas art not shown in FIG. 3, because such a layout is well known in the prior art.

In step (b), a lithography process using a mask having the same opaque pattern of the Alt-PSM 10 of FIG. 1B is performed to pattern the photoresist layer 320. The mask is not necessarily an Alt-PSM like the Alt-PSM 10, and each pair of zero-shift region 16 and π-shift region 14 can be replaced with two transparent regions without any phase shift between them when a larger trimming bias is set allowing the narrower photoresist pattern to be formed wider without aid of phase shift patterns. With the patterning process, openings 322 corresponding to the transparent regions on the mask are formed in the photoresist layer 320, exposing portions of the material layer 310 and defining a narrower pattern 320a between each pair of adjacent openings 322.

In step (c), a trimming step is conducted to reduce the width of the narrower pattern 320a to a predetermined width, as indicated by the small arrows. Since there is no line end of the narrower pattern 320a present, no line-end shortening occurs in the trimming step.

In step (d), the material layer 310 is etched using the patterned photoresist layer 320 as a mask, so that openings 312 are formed in the material layer 310 exposing portions of the substrate 300 and defining the narrower patterns 310a in the trimming-reduced width with no line end. The patterned photoresist layer 320 is then removed.

In step (e), a new photoresist layer 330 is formed over the substrate 300 and then patterned using a mask having the same pattern of the mask 20 of FIG. 1B, wherein the mask may be a binary mask or a half-tone mask on which the pattern (24) is formed from a material of low transparency. The patterned photoresist layer 330 defines the wider portions of the target pattern and also covers the narrower portions 310a, while the line end position of each narrower portion 310a requiring a line end in design is passed by a boundary of the patterned photoresist layer 330.

In step (f), the material layer 310 is etched again using the patterned photoresist layer 330 as a mask, so that wider patterns 310b are formed. Meanwhile, since the line end position of each narrower portion 310a requiring a line end in design is passed by a boundary of the patterned photoresist layer 330, each of such narrower portions 310a is cut by the etching at the predetermined line-end position to form a line end thereof. The narrower portions 310a, which include those having a line end and those without a line end, and the wider portions 310b together constitute the target pattern 310c. After that, the patterned photoresist layer 330 is removed.

Moreover, the pair of transparent regions (e.g., the pair of zero-shift region 16 and π-shift region 14) for defining a narrower portion 310a with a line end may be designed substantially extending beyond the corresponding line-end position on the first mask (e.g., Alt-PSM 10), so as to make the narrower pattern 320a and 310a respectively in steps (c) and (d) substantially extend beyond the predetermined line-end position. Thus, even if the photoresist layer 330 formed later is mis-aligned in the direction of the line end making the boundary thereof exceeding the predetermined line-end position, a narrow line end can still be defined successfully.

Alternatively, the patterning process using the second mask 20 can be conducted before that using the first mask (e.g., Alt-PSM 10), while a trimming step can also be performed to the patterned photoresist layer formed with the first mask in such cases. Briefly speaking, in the alternative method, a patterned photoresist layer 330 as shown in FIG. 3(e) is firstly formed on the undefined material layer 310. Then, an etching step is conducted to form a patterned material layer that has the same shape of 330 and includes the wider portions 310b, wherein the line end of each narrower portion 310a requiring a line end in design is also defined. After the patterned photoresist layer 330 is removed, a patterned photoresist layer 320 as shown in FIG. 3(b) is formed over the substrate 300 including the openings 322 and the narrower patterns 320a, and then a trimming step is conducted to reduce the width of each narrower pattern 320a, as shown in step (c). The exposed portions of the previously patterned material layer beside each narrower portion 310a are removed in the subsequent etching step to form the narrower portions 310a, and then the patterned photoresist layer 320 is removed to complete the patterning process.

Since there is no line end of the narrower photoresist patterns present in the trimming step and the line ends of the target pattern are defined by another photoresist pattern formed with another mask without being trimmed, no line-end shortening occurs to the narrower portions of the target pattern.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for forming a target pattern having a narrower portion and a wider portion, comprising:
(a) providing a substrate having a material layer thereon;
(b) providing a first mask and a second mask, wherein the first mask has a first pattern including a pattern of the narrower portion and also covering an area of the wider portion, and the second mask has a second pattern including a pattern of the wider portion and also covering an area of the narrower portion;
(c) using the first mask to form a first photoresist pattern over the substrate;
(d) etching the material layer with the first photoresist pattern as a mask;
(e) removing the first photoresist pattern;
(f) using the second mask to form a second photoresist pattern over the substrate;
(g) etching the material layer with the second photoresist pattern as a mask; and
(h) removing the second photoresist pattern.

2. The method according to claim 1, further comprising a step of trimming the first photoresist pattern between the steps (c) and (d).

3. The method of claim 1, wherein the steps (f), (g) and (h) are performed sequentially after the step (b) and before the steps (c), (d) and (e).

4. The method of claim 1, wherein the first mask comprises an opaque layer and two transparent regions in the opaque layer, and a portion of the opaque layer between the two transparent regions corresponds to the narrower portion of the target pattern.

5. The method of claim 4, wherein the narrower portion of the target pattern has a line end, and the second pattern of the second mask has a boundary passing a corresponding position of the line end on the second mask.

6. The method of claim 5, further comprising a step of trimming the first photoresist pattern between the steps (c) and (d).

7. The method of claim 5, wherein the two transparent regions substantially extend beyond the corresponding position of the line end on the second mask.

8. The method of claim 4, wherein the first mask is an alternating phase-shift mask, and the two transparent regions comprise a pair of zero-shift region and π-shift region.

9. The method of claim 1, wherein the second mask is a binary or half-tone mask.

10. The method of claim 1, wherein
the target pattern comprises a gate line pattern;
the wider portion of the target pattern comprises a portion of the gate line pattern located on a field isolation layer; and
the narrower portion of the target pattern has at least one line end, and the second pattern of the second mask has a boundary passing a corresponding position of the line end on the second mask.

11. The method of claim 10, wherein the gate line pattern comprises a split-gate pattern.

12. The method of claim 10, wherein the first mask comprises an opaque layer and two transparent regions in the opaque layer, and a portion of the opaque layer between the two transparent regions corresponds to the narrower portion of the target pattern.

13. The method of claim 12, wherein the narrower portion of the target pattern has a line end, and the second pattern of the second mask has a boundary passing a corresponding position of the line end on the second mask.

14. The method of claim 13, further comprising a step of trimming the first photoresist pattern between the steps (c) and (d).

15. The method of claim 13, wherein the two transparent regions substantially extend beyond the corresponding position of the line end on the second mask.

16. The method of claim 12, wherein the first mask is an alternating phase-shift mask, and the two transparent regions comprise a pair of zero-shift region and π-shift region.

17. A method for forming a composite pattern including different types of patterns, comprising:
(a) providing a substrate having a material layer thereon;
(b) providing a plurality of masks each having at least one type of pattern thereon;
(c) using one mask to form one photoresist pattern over the substrate;
(d) patterning the material layer with the photoresist pattern as a mask;
(e) removing the photoresist pattern; and
(f) repeating the steps (c), (d) and (e) in sequence for a plurality of cycles, with a different mask being used in each cycle, until all of the masks have been used,
wherein an imaginary pattern defined by an overlap between the patterns of all of the masks includes the at least one type of pattern of each mask.

18. The method of claim 17, wherein the composite pattern includes two types of patterns and two masks are used, wherein each mask has one type of pattern.

19. The method of claim 18, wherein the two masks include:
a first mask having a narrower pattern thereon; and
a second mask having a wider pattern thereon.

20. The method of claim 19, further comprising a trimming step conducted to the photoresist pattern formed with the first mask.

21. The method of claim 19, wherein the first mask is used before or after the second mask.

22. The method of claim 19, wherein the first mask is a phase-shift mask (PSM).

23. The method of claim 22, wherein the PSM is an alternating phase-shift mask (Alt-PSM).

24. The method of claim 19, wherein the second mask is a binary mask or a half-tone mask.
